(19) United States
(12) Patent Application Publication
(10) Pub. No.: US 2017/0130061 A1
(43) Pub. Date: May 11, 2017

(54) HYBRID PARYLENE-METAL OXIDE INTERSTACKED COATINGS

(71) Applicant: HZO, Inc., Draper, UT (US)

(72) Inventors: Layton Baker, Draper, UT (US); Sean Clancy, Draper, UT (US); Chien-Lan Hsueh, Draper, UT (US)

(73) Assignee: HZO, Inc., Draper, UT (US)

(21) Appl. No.: 15/347,649

(22) Filed: Nov. 9, 2016

Related U.S. Application Data
(60) Provisional application No. 62/253,015, filed on Nov. 9, 2015.

(51) Int. Cl. C09D 5/08; C23C 16/44; C23C 16/22

(52) U.S. Cl. CPC C09D 5/084; C09D 5/086; C23C 16/22; C23C 16/44

(57) ABSTRACT

Described herein is a composite coating on a substrate including a first parylene layer deposited on a substrate surface of a substrate, a first metal oxide layer covering the first parylene layer, a first metal oxide, parylene hybrid layer formed between the first metal oxide layer and the first parylene layer. The composite coating further includes a second parylene layer covering the first metal oxide layer, with the first metal oxide layer interposed between the first and second parylene layers.

### CROSS-REFERENCES TO RELATED APPLICATIONS

This application claims the benefit of U.S. Provisional Patent Application No. 62/253,015 entitled “HYBRID PARYLENE-METAL OXIDE INTERSTACKED COATINGS” and filed on Nov. 9, 2015 for Layton Baker et al., which is incorporated herein by reference.

### TECHNICAL FIELD

This disclosure relates generally to coatings and methods of preparing components within an electronic device with corrosion resistant coatings. More specifically, the disclosed subject matter relates to coatings and methods of preparing electronic components with enhanced parylene coatings to impart the components with resistance to corrosive chemical species.

### BACKGROUND

The durability of electronic devices in harsh environmental conditions is of major interest in industrial and consumer electronics. In electronic applications, electronic assemblies are frequently exposed to corrosive environments (e.g., high temperatures, water, steam, acids, organic solvents, salt, etc. and combinations thereof) which can cause rapid failure of electronic components and circuits on the electronics assembly. In consumer electronics, the most common corrosive environmental exposures are accidental water spray or immersion. Electronics are commonly housed within a protective case or enclosure which is designed, in part, to limit exposure of the electronics assembly and components to water and other corrosive solids, liquids, and gases. The protective cases/enclosures typically do not provide complete protection and add volume and mass to electronic products.

An alternative to corrosion-resistant cases arises from encapsulating the underlying electrical components within device enclosures. For example, a thin film or protective coating can be applied to the electronic circuitry and/or components inside of an electronic device. This protective coating fully encapsulates and protects the electronic device from corrosive chemical species, such as water, without requiring a bulky external protective case. Such corrosion-resistant coatings are desirable for protection against incidental or accidental exposure to water and other corrosive species. For instance, a thin film coating may protect the electronic components of a consumer electronics device from corrosion, and eventual failure, due to high humidity, rain, spilled drinks, immersion or even full submersion in water.

There remains, therefore, a need in the art to provide alternative coatings that might be applied to the circuitry and components of an electronic device that offer extended protection from corrosive chemical species exposure, as well resistance to mechanical handling and wear and that might impart additional desirable properties such as electromagnetic resistance, oxidation resistance, or desirable optical properties.

### SUMMARY

The subject matter of the present application has been developed in response to the present state of the art, and in particular, in response to the shortcomings of electronic device and substrate coatings, that have not yet been fully solved by currently available techniques. Accordingly, the subject matter of the present application has been developed to provide a composite coating with a metal oxide, parylene hybrid layer to overcome at least some of the above-discussed shortcomings of prior art techniques.

According to one embodiment, a composite coating on a substrate includes a first parylene layer deposited on a substrate surface of a substrate, a first metal oxide layer covering the first parylene layer, a first metal oxide, parylene hybrid layer formed between the first metal oxide layer and the first parylene layer. The composite coating further includes a second parylene layer covering the first metal oxide layer, with the first metal oxide layer interposed between the first and second parylene layers. In some implementations, the first metal oxide, the parylene hybrid layer is located within an outer layer of the first parylene layer.

In certain implementations of the composite coating, the parylene is selected from parylene A, parylene C, parylene N, parylene D, parylene VT-4, parylene AF-4, as well as mixtures and/or derivations of the same. In some embodiments, the polymer is selected from parylene C and parylene N.

According to some implementations of the composite coating, the first metal oxide layer is formed by oxidation of a metal oxide precursor defined by formula I: [M]-(R1)n where M is a metal, each R1 is selected from or is at least one of hydrogen, C1-C12 alkyl, C1-C12 alkoxide, halogen, alkyl halide, C1-C12 alkylamido, di-C1-C12 alkylamido, optionally substituted cyclopentadienyl, and n corresponds to the oxidation state of the metal.

In some embodiments, the metal is one or more selected from a group including aluminum, gallium, magnesium, hafnium, silicon, tantalum, titanium, yttrium, zinc, and zirconium.

In some embodiments, at least one R¹ is hydrogen, C₁-C₁₂ alkyl, or partially or completely halogenated C₁-C₁₂ alkyl. In some embodiments, at least one R¹ is a halogen selected from the group consisting of fluorine, chlorine, and bromine, or an alkoxide selected from the group consisting of iso-propoxide and butoxide. In some embodiments, at least one R¹ is optionally substituted cyclopentadienyl.

In some embodiments, the composite coating also includes a second metal oxide layer covering a surface of the second parylene layer.

In some embodiments, the first and second parylene layers are made from the same parylene material. In some embodiments, the parylene layers are made from the different parylene materials.

In some embodiments, the second metal oxide layer is formed by oxidation of a metal oxide precursor defined by formula I: [M]-(R¹)ₙ where M is a metal, each R¹ is selected from or is at least one of hydrogen, C₁-C₁₂ alkyl, C₁-C₁₂ alkoxide, halogen, alkyl halide, C₁-C₁₂ alkylamido, di-C₁-C₁₂ alkylamido, optionally substituted cyclopentadienyl, and n corresponds to the oxidation state of the metal.

In some embodiments, each metal oxide layer has a thickness of about and inclusive of 5 to about 50 nm. In some embodiments, the first parylene layer has a thickness of about and inclusive of 0.1 μm to about 2 μm. In some embodiments, the composite coating further comprises additional parylene layers and additional metal oxide layers in an alternating arrangement up to a maximum composite coating thickness of from about 0.5 μm to about 20 μm.

According to one embodiment, a process for depositing a composite coating on a substrate is disclosed. The method includes applying a first parylene layer to a substrate surface of a substrate, depositing a first metal oxide precursor onto a surface of the first parylene layer to cover the first parylene layer, oxidizing the first metal oxide precursor to form a first metal oxide layer, and applying a second parylene layer onto a surface of the first metal oxide layer.

In some embodiments, the parylene is selected from parylene A, parylene C, parylene N, parylene D, parylene VT-4, parylene AF-4, as well as mixtures and derivatives of the same.

In some embodiments, the surface of the parylene layer or polymer film is modified by infusion of a metal oxide precursor of the formula I: [M]-(R¹)ₙ where M is a metal, each R¹ is selected from hydrogen, C₁-C₁₂ alkyl, C₁-C₁₂ alkoxide, halogen, C₁-C₁₂ alkylamido, di-C₁-C₁₂ alkylamido, optionally substituted cyclopentadienyl, and n corresponds to the oxidation state of the metal.

In some embodiments, the metal is selected from aluminum, gallium, magnesium, hafnium, silicon, tantalum, titanium, yttrium, zinc, and zirconium.

In one aspect, a coated corrosive sensitive article prepared from the processes disclosed herein is also disclosed.

The described features, structures, advantages, and/or characteristics of the subject matter of the present disclosure may be combined in any suitable manner in one or more embodiments and/or implementations. In the following description, numerous specific details are provided to impart a thorough understanding of embodiments of the subject matter of the present disclosure. One skilled in the relevant art will recognize that the subject matter of the present disclosure may be practiced without one or more of the specific features, details, components, materials, and/or methods of a particular embodiment or implementation. In other instances, additional features and advantages may be recognized in certain embodiments and/or implementations that may not be present in all embodiments or implementations. Further, in some instances, well-known structures, materials, or operations are not shown or described in detail to avoid obscuring aspects of the subject matter of the present disclosure. The features and advantages of the subject matter of the present disclosure will become more fully apparent from the following description and appended claims, or may be learned by the practice of the subject matter as set forth hereinafter.

### BRIEF DESCRIPTION OF THE DRAWINGS

In order that the advantages of the present subject matter will be readily understood, a description of the present subject matter will be rendered by reference to specific embodiments that are illustrated in the appended drawings. Understanding that these drawings depict only typical embodiments of the present subject matter and are not therefore to be considered to be limiting of its scope, the present subject matter will be described and explained with detail through the use of the accompanying drawings, in which:

FIG. 1 is a cross-sectional view of a substrate with a parylene coating, according to one or more embodiments of the present disclosure;

FIG. 2 is a cross-sectional view of a substrate with a composite coating, according to one or more embodiments of the present disclosure; and

FIG. 3 is a schematic diagram of a process for depositing a composite coating on a substrate, according to one or more embodiments of the present disclosure.

### DETAILED DESCRIPTION

Reference throughout this specification to “one embodiment,” “an embodiment,” or similar language means that a particular feature, structure, or characteristic described in connection with the embodiment is included in at least one embodiment of the present disclosure. Appearances of the phrases “in one embodiment,” “in an embodiment,” and similar language throughout this specification may, but do not necessarily, all refer to the same embodiment. Similarly, the use of the term “implementation” means an implementation having a particular feature, structure, or characteristic described in connection with one or more embodiments of the present disclosure, however, absent an express correlation to indicate otherwise, an implementation may be associated with one or more embodiments.

In order that the advantages of the subject matter may be more readily understood, a more particular description of the subject matter briefly described above will be rendered by reference to specific embodiments that are illustrated in the appended drawings. Understanding that these drawings depict only typical embodiments of the subject matter and are not therefore to be considered to be limiting of its scope, the subject matter will be described and explained with additional specificity and detail through the use of the drawings.

The term “corrosion resistant” refers to the ability of a coating to prevent exposure of a coated element or feature to corrosive chemical species. With the context of an electronic device, corrosive chemical species include any chemical, gas, liquid, or solid, which causes or facilitates degradation of materials on the electronic device. Examples of such corrosive chemical species include, but are not limited to, (a) humid warm air, (b) liquid water, (c) salts such as from seas and oceans (e.g., salt water immersion; humid, salty air in coastal environments), (d) organic vapors and liquids such as diesel fuel, jet fuel, gasoline, acetone, alcohols, and mixtures thereof, (e) acids such as aqueous hydrochloric acid or hydrochloric acid vapor, (f) bases such as aqueous ammonia or ammonia vapor, and (g) gaseous corrosive species such as sulfur dioxide and sulfur trioxide, which may adsorb on the surface of electronic components. A corrosion resistant coating may resist wetting or penetration by one or more types of corrosive chemical species, or it may be impermeable or substantially impermeable to one or more types of corrosive chemical species. A corrosion resistant coating may repel one or more types of corrosive chemical species such as salt solutions, acidic solutions, basic solutions, drinks, etc. or vapors of water or other aqueous materials (e.g., humidity, fogs, mists, etc.), wetness, etc. Use of the term “corrosion resistant” to modify the term “coating” should not be considered to limit the scope of materials from which the coating protects one or more components of an electronic device. The term “corrosion resistant” may also refer to the ability of a coating to restrict permeation of or repel organic liquids or vapors (e.g., organic solvents, other organic materials in liquid or vapor form, etc.), as well as a variety of other substances or conditions that might pose a threat to a substrate, such as an electronic device or its components.

As used herein, the terms “composite coating” and “composite-like coating” refer to a combination of interstacked/interdigitated layers of parylene material and metal oxide, and may include a near surface region of the parylene material where metal oxide is also present in the parylene material, having diffused into the near surface region as a metal oxide precursor which subsequently oxidizes into a metal oxide. The resulting near surface region of the parylene material is a hybrid material made up of parylene polymer and metal oxide. The composite coating may be also be referred to as a multilayer coating or laminate coating/nanolaminate coating. It is also understood that the term ‘coating’ and ‘thin film’ may be used interchangeably.

Coating systems, or, more simply, coatings, for imparting substrates with corrosion resistance are disclosed. Such a coating may be used on any suitable substrate, including, without limitation, components that will reside within the interior of an electronic device.

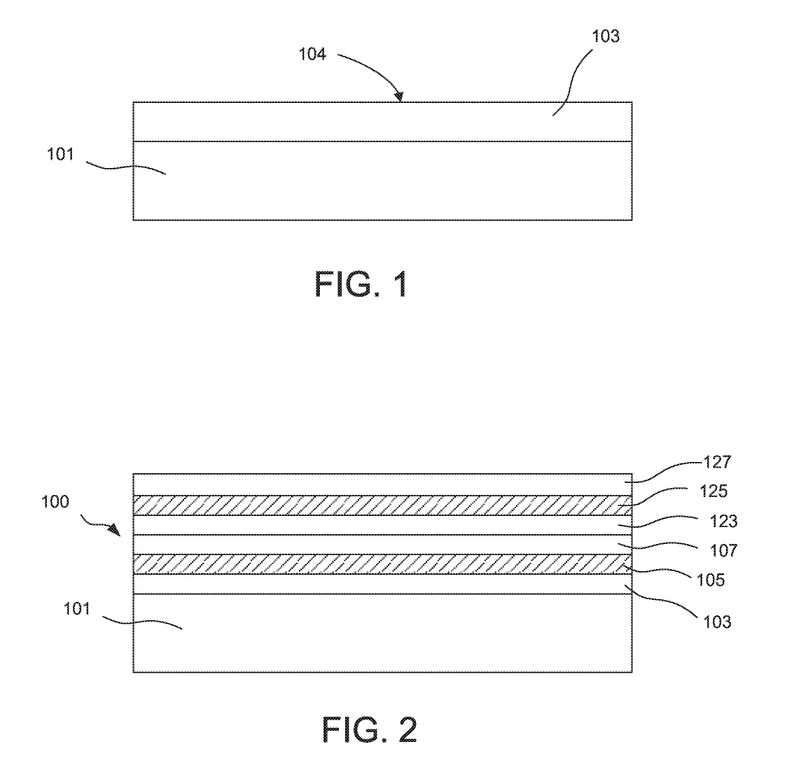

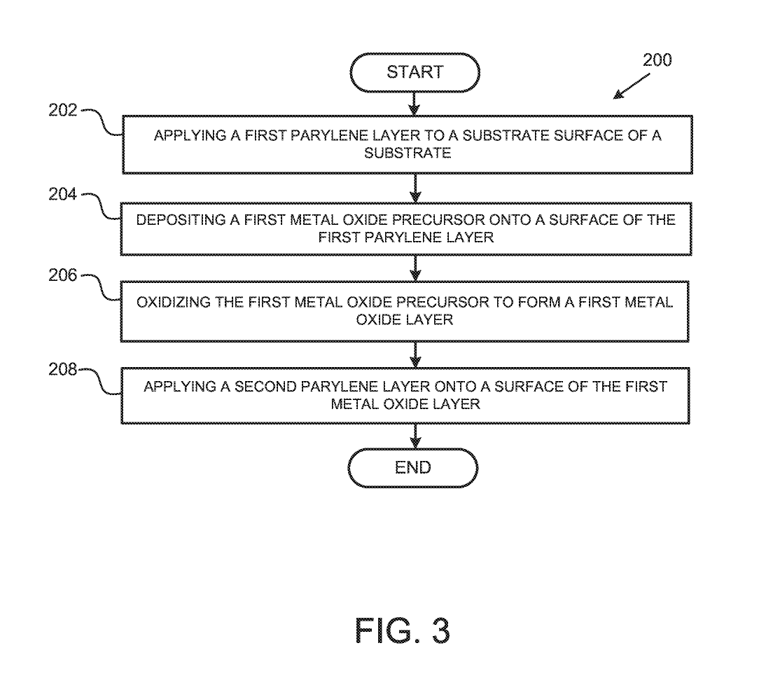

A series of composite, multilayer coatings made up of interdigitated, parylene layers and metal oxide layers is described herein. Referring to FIG. 1, a cross-sectional view of a substrate 101 with a parylene coating or parylene layer 103 is shown. The parylene layer 103 includes an outer surface 104 onto which a metal oxide precursor may be interspersed which is described in more detail in conjunction with FIGS. 2 and 3.

Referring to FIG. 2, a representative embodiment of the composite coating 100 is shown. Each metal oxide layer is derived from a physical vapor deposition, metal oxide chemical vapor deposition, or atomic layer deposition process. Beneath the metal oxide layer 107, 127 at the interface between the metal oxide layer 107, 127 and the parylene layer 103, 123 may be an interspersion or metal oxide, parylene hybrid layer 105, 125 of parylene and metal oxide derived from the infusion of metal oxide precursor that subsequently oxidizes to form metal oxide. The interspersion may also be referred to as a metal-organic hybrid layer or zone in which metal oxide precursor has diffused into the parylene layer 103, 123. Thus, as shown in FIG. 2, a substrate 101 is covered by a first parylene layer 103. A first metal oxide layer 107 is adjacent to the first parylene layer 103 with a first metal oxide, parylene hybrid layer 105 may be present and is made up of an interspersion of parylene and metal oxide derived from the infusion of metal oxide precursor that subsequently oxidizes to form metal oxide. A second parylene layer 123 is adjacent to the first metal oxide layer 107. A second metal oxide, parylene hybrid layer 125 may be present and is made up of an interspersion of parylene in the second parylene layer 123 and metal oxide 127 derived from the infusion of metal oxide precursor that subsequently oxidizes to form metal oxide. The composite coating 100 may also be referred to herein as a metal-organic multilayer coating or film, or metal-organic laminate/nano-laminate coating or film

An in situ surface treatment process for producing the composite coating 100 is also described herein. The composite coating 100 covers some or all of a substrate 101, with the substrate 101 disposed beneath the first parylene layer 103. Exemplary substrates 101 include components configured to be within an interior of an electronic device, such as a printed circuit board assembly (PCBA). The composite coating 100 with the metal-organic hybrid layer provides enhanced properties, such as, for example, UV blocking, improved oxidation resistance, wear resistance, and water and corrosion resistance, to substrates.

In some variations of the metal-organic multilayer coating process, a metal-organic hybrid interspersion layer or metal oxide, parylene hybrid layer 105 may be formed in a parylene layer 103 near the metal oxide/parylene interface. During the nucleation phase of the metal oxide formation, molecules of the metal oxide precursor initially cover the surface of a parylene film or parylene layer 103. For example, the metal oxide precursor may form a monolayer or multi-layer on the surface of a parylene layer 103. The metal oxide precursor may also diffuse into the top or near surface portion of the parylene layer 103, forming an interspersion of the metal oxide precursor in the parylene layer 103. Further, the metal oxide precursor may subsequently oxidize in an oxidizing environment (for example, water, air, and/or oxygen) thus forming a metal oxide layer 107 covering the parylene layer 103. Inasmuch as the metal oxide precursor that has interspersed into the parylene layer 103 comes into contact with the oxidant source, such as by diffusion, the interspersed precursor also oxidizes so that metal oxide is interspersed within the parylene layer 103. The resulting material within the parylene layer 103 and near the metal oxide/parylene interface is a hybrid layer 105 of parylene and metal oxide.

A variety of parylene materials may be used. As generally known in the art, parylene includes a variety of a number of unsubstituted and substituted poly(para-xylylene). Exemplary parylenes include parylene A (amino-modified parylene), parylene C (poly(chloro-p-xylylene)), parylene N (poly(p-xylylene)), parylene D (poly(dichloro-p-xylylene)), parylene F (which can specifically refer to parylene-VT4, parylene-AF4, or any other parylene with a fluorine atom or atoms in the molecular structure), as well as mixtures and derivatives thereof.

The composite coating may be applied in multiple layers. For example, the composite coating may comprise a series of parylene layers 103, 123 and metal oxide layers 107, 127 in an alternating arrangement. In one embodiment, the composite coating 100 may include a first parylene layer 103 applied to a substrate 101, and that first parylene layer 103 is also covered by a first metal oxide layer 107, with a second parylene layer 123 covering the first metal oxide layer 107. In this exemplary arrangement, the coating system has three layers, with the first metal oxide layer 107 being interposed between the first and second parylene layers 103, 123. The parylene layers 103, 123 may be the same parylene material. In some embodiments, the parylene layers 103, 123 may be different parylene materials.

In another example, the composite coating 100 may include four layers arranged as follows: a first parylene 103 on a substrate 101, a first metal oxide layer 107, a second parylene layer 123, and a second metal oxide layer 127. In these embodiments, the substrate 101 is in contact with the first parylene layer 103 rather than the first metal oxide layer 107.

In a multi-layer composite coating 100, the material of construction for the plurality of parylene films or layers 103, 123 may be the same parylene material or may be different parylene materials. For example, in a four layer composite coating 100, first and second parylene layers 103, 123 may both be parylene C. In an alternative embodiment with four layers, a first parylene layer 103 is parylene N, and a second parylene layer 123 is parylene C. Similarly, the material of construction for the plurality of metal oxide precursor layers may be the same material or different materials. For example, in a four layer composite coating, first and second metal oxide layers 107, 127 may both be aluminum oxide (Al₂O₃). In an alternative exemplary four layer composite coating, a first metal oxide layer 107 may be aluminum oxide (Al₂O₃) and a second metal oxide layer 127 may be titanium oxide (TiO₂). Moreover, each metal oxide layer may, itself, be comprised of alternating layers of two or more metal oxides; such a metal oxide layer may be described as a multilayer or nano-laminate metal oxide film. An exemplary multilayer or nano-laminate metal oxide film would be interstacked layers of aluminum oxide and titanium oxide (e.g., Al₂O₃/TiO₂/Al₂O₃/TiO₂) with interstacked parylene materials between metal oxide layers.

In the composite coating, each metal oxide layer 107, 127 covers a parylene layer 103, 123. Additionally, a portion of the metal oxide precursor may diffuse into upper or near surface portions of the parylene layers 103, 123. Thus, one of ordinary skill in the art will understand that for the purposes of this application the terms “cover”, “covers”, and “covering” encompass embodiments where the metal oxide layer 107, 127 forms a layer on top of the parylene layer 103, 123 and disperses into a near surface portion of the parylene layer 103, 123 from diffusion into the parylene layer 103, 123 thereby filling in void defects or gaps that may be present in the parylene layer 103, 123.

Each metal oxide layer 107, 127 may have a thickness from about and inclusive of 0.1 nm to about 100 nm. In some embodiments, the metal oxide layer 107, 127 is from about and inclusive of 0.1 nm to about 50 nm. In some embodiments, the metal oxide layer 107 from about and inclusive of 0.1 nm to about 20 nm. The metal oxide precursor that diffuses into the parylene layer 103 or polymer film may diffuse to a depth of up to about 500 nm or more into the parylene layer 103. In some embodiments, the metal oxide precursor that diffuses into the parylene layer 103 does so to a depth of up to about 200 nm. In some embodiments, the metal oxide precursor that diffuses into the parylene layer 103 does so to a depth of up to about 100 nm.

Each parylene layer 103, 123 may have a thickness from about and inclusive of 0.3 microns (μm) to about 4 μm. In some embodiments, the thickness is from about and inclusive of 0.4 μm to about 3 μm. In some embodiments, the thickness is from about and inclusive of 0.5 μm to 2 μm. In some embodiments, the thickness is from about and inclusive of 0.1 μm to about 2 μm. In some embodiments, the thickness is from 0.5 μm to about and inclusive of 20 μm

The total thickness of the composite coating 100, which may include a single parylene layer and single metal oxide layer or a plurality of parylene layers and a plurality of metal oxide layers, may be from about and inclusive of 1 μm to about 25 μm. In some embodiments, the total thickness of the composite coating is from about and inclusive of 1 μm to about 15 μm. In some embodiments, the total thickness of the composite coating is from about and inclusive of 1 μm to about 8 μm. The total thickness of the composite coating is variable to provide the properties for the underlying substrate and the article in which it is incorporated. Factors such as intended use (i.e., desired barrier properties for a particular use) and manufacturing deposition time may be considered when determining the total thickness for a particular composite coating 100.

Embodiments of the composite coating 100 may have enhanced properties relative to the parylene layer 103 by itself. For example, transmission of water and other molecules through the composite material may be reduced by the metal oxide covering the surface of the parylene layer 103 and depositing into defects, voids, and/or imperfections in the surface of a parylene only coating. Further, any diffused metal oxide precursor into the parylene material and subsequent formation of metal oxide via oxidation will densify or increase the density in the near surface layer of the parylene material, thus also reducing transmission of water and other molecules through the composite material. Further, a metal oxide covering resulting from oxidation of the metal oxide precursor applied to the parylene can provide UV resistance, with some metal oxides potentially providing greater resistance than others. For example, titanium oxide and zinc oxide may provide enhanced UV protection to an underlying parylene layer 103. Additionally, a metal oxide top layer may inhibit degradation of parylene in high temperature oxidative environments (for example, hot air) by providing a diffusion barrier above the parylene layer 103. Further, the composite coating 100 may exhibit improved scratch and wear tolerance. Further, the optical properties of a parylene film or layer (for example, transmission and color) can be modified by adjusting the thickness and properties of the metal oxide layer 107. For example, coloring of the parylene layer 103 may help with optical inspection of a coated substrate. Further, covering of the parylene layer 103 with a metal oxide layer 107 may impart novel optical properties to parylene (for example, notch/band-stop/band-pass filter functions). In addition, certain metal oxides may be used to modify the electrical properties of the parylene layer 103. For example, zinc oxide may be used to make the parylene film surface semiconducting for electrostatic discharge (ESD) mitigation issues.

In some embodiments the metal oxide precursor includes both metal-organic and metal-halide chemical species and may be defined by the formula I: [M]-(R¹)ₙ where M is a metal, and where each R¹ is selected from or at least one of hydrogen, C₁-C₁₂ alkyl, C₁-C₁₂ alkoxide, halogen, alkyl halide, C₁-C₁₂ alkylamido, di-C₁-C₁₂ alkylamido, optionally substituted cyclopentadienyl, and n corresponds to the oxidation state of the metal. Exemplary halogens may include fluorine, chlorine, or bromine. Exemplary alkoxides may include iso-propoxide or butoxide.

The metal M in formula I can be selected from any non-toxic metal including transition metals and post-transition metals. For example, the metal may be selected one or a combination of the following metals, including aluminum, gallium, magnesium, hafnium, silicon, tantalum, titanium, yttrium, zinc, and zirconium.

Exemplary metal oxide precursors may include the following:

For precursors wherein the metal is aluminum: trimethyl-aluminum, dimethyl-aluminum hydride, triethyl aluminum, aluminum tribromide, aluminum chloride, triisopropyl-aluminum, dimethylaluminum isopropoxide, aluminum sec-butoxide, tris(diethylamido)-aluminum, tris(ethylmethylamido)-aluminum, and diethyl-aluminum ethoxide;

For precursors wherein the metal is gallium: trimethyl gallium, dimethyl-gallium hydride, triethyl-gallium, triisopropyl-gallium, gallium tribromide, gallium trichloride, tris(dimethylamido)gallium, and tri-tert-butyl-gallium;

For precursors wherein the metal is magnesium, magnesium chloride, bis(cyclopentadienyl)magnesium, bis(ethylcyclopentadienyl)magnesium, bis(pentaethylcyclopentadienyl)magnesium, bis(pentamethylcyclopentadienyl)magnesium, bis(n-propylcyclopentadienyl)magnesium, and bis(2,2,6,6-tetramethyl-3,5-heptanedionato)magnesium;

For precursors wherein the metal is hafnium, hafnium chloride, hafnium tert-butoxide, tetrakis(ethylmethylamido)hafnium, and tetrakis(diethylamido)hafnium, tetrakis(dimethylamido)hafnium;

For precursors wherein the metal is silicon, silane, disilane, trisilane, tetramethylsilane, trimethylsilane, tetradeuterosilane (silane-d4), silicon chloride, bis(tertiary-butylamino)silane (BTBAS), bis(diethylamino)silane (BDEAS), tetratetraethoxysilane (TEOS), tetramethylcyclotetrasiloxane, dimethoxydimethylsilane, octamethylcyclotetrasiloxane, tris(isoproxy)silanol, tris(tert-butoxy)silanol, and tris(tert-pentoxy) silanol;

For precursors wherein the metal is tantalum, tantalum ethoxide, tantalum butoxide, tantalum methoxide, and pentakis(dimethylamino)tantalum;

For precursors wherein the metal is titanium, titanium chloride, titanium ethoxide, titanium isoproxide, titanium butoxide, tetrakis(dimethylamino)titanium, and tetrakis(diethylamino)titanium;

For precursors wherein the metal is yttrium, tris(R′-cyclopentadienyl)yttrium [where R′=none, methyl, ethyl, propyl, butyl], yttrium hexafluoroacetylacetonate, and tris(2,2,6,6-tetramethyl-3,5-heptanedionato)yttrium;

For precursors wherein the metal is zinc, diethyl zinc, dimethyl zinc, and bis(2,2,6,6-tetramethyl-3,5-heptanedionato)zinc; and

For precursors wherein the metal is zirconium, zirconium chloride, zirconium ethoxide, zirconium tert-butoxide, tetrakis(dimethylamino)zirconium, tetrakis(diethylamino)zirconium, tetrakis(methylethylamino)zirconium, zirconium hexafluoroacetylacetonate, zirconium trifluoroacetylacetonate, tetrakis(2,2,6,6-tetramethyl-3,5-heptanedionato)zirconium, and bis(cyclopentadienyl)dimethylzirconium.

As mentioned above, the composite coating 100 may cover a substrate, with the substrate 101 disposed beneath and in contact with the first parylene layer 103 or polymer film. Exemplary substrates 101 may include components configured to be within an interior of an electronic device, such as within the interior of housing for the device. For example, the substrate 101 may be a printed circuit board assembly or PCBA. In other embodiments, the composite coating 100 may cover at least some components that are exposed to the outside of the electronic device. Exemplary substrates 101 may also include a component of a mobile electronic device, an energy storage device such as a battery, an industrial device, a vehicular device, a precision mechanical device, a medical device, a scientific instrument, an article of clothing or the like. A substrate 101 that has been coated with the composite coating 100 described herein may be referred to as a coated article. Although shown as a layer, in some embodiments, the composite coating 100 may fully or partially encapsulate the substrate 101.

Methods for applying the composite coating 100 to a substrate 101 to produce a coated article are described. The layers of the composite coating 100 may be applied in a single process or in two or more processes wherein different materials are applied to a substrate 101. As will be discussed in greater detail below, it is desirable to reduce or eliminate the presence of air and other oxidants during the coating process.

Referring to FIG. 3, a schematic diagram of a process 200 for depositing a composite coating on a substrate is shown. The process 200 includes applying 202 a first parylene layer to a substrate surface of a substrate. The process 200 includes depositing 204 a first metal oxide precursor onto a surface of the first parylene layer to cover the first parylene layer. The process 200 further includes oxidizing 206 the first metal oxide precursor to form a first metal oxide layer. The process 200 further includes applying 208 a second parylene layer onto a surface of the first metal oxide layer. The depicted process 200 then ends.

In some embodiments, the discrete processes may be carried out by the same equipment, even in the same application zone (e.g., deposition chamber, etc.), or by separate pieces of equipment (e.g., a chemical vapor deposition (CVD) chamber for parylene and an atomic layer deposition (ALD) chamber for the metal oxide precursor).

In an exemplary embodiment, a parylene layer 103 is deposited on a substrate 101 by chemical vapor deposition. The chemical vapor deposition process includes three major steps: vaporization, pyrolysis, and polymerization. The parameters of each stage can be determined for each material or combination of materials. For example, the vaporizer may operate in a temperature range of 120-170° C., the pyrolysis furnace may operate at a temperature range of about and inclusive of 550-650° C., and the deposition chamber may operate at a temperature range of about and inclusive of 20-150° C.

In an exemplary embodiment of a parylene-C deposition process, the vaporizer temperature is controlled between 150° C. to 165° C. to produce a consistent vapor pressure of dimer in the range of 600-800 mTorr, as measured by pressure sensor in the vaporizer section of deposition tool. Dimer vapor flows through the pyrolysis sub-system, which is operated between 580° C. and 610° C., where dimer is thermally cracked into monomer; the precise operating temperature of the pyrolysis sub-system is set dynamically based upon the molecular flow rate of dimer into the pyrolysis sub-system. The molecular flow rate is determined empirically from the absolute pressure of dimer in the vaporizer and the pressure of monomer in the deposition system. Monomer flows from the pyrolysis sub-system into the deposition chamber where parylene is deposited onto all exposed surfaces via an initial nucleation step followed by chain polymerization. The initial surface temperature of electronic parts and chamber surfaces is near ambient temperature at the beginning of the deposition process and slowly increases during the deposition process due to exothermic nature of parylene chain polymerization.

The metal oxide precursor, for example trimethyl aluminum, can then be exposed to the parylene layer 103, 123. It is desirable that the metal oxide precursor layer forms a monolayer or multilayer on the parylene top surface and also diffuses into the bulk of the parylene film in the upper portion of the parylene layer 103, 123. The metal oxide precursor layer may also fill micro porous structures, voids, defects, and the like in and on the parylene layer 103, 123.

An exemplary embodiment of a metal precursor exposure process is described as follows. After the completion of the parylene deposition process, the deposition chamber is evacuated to base pressure (approximately 1-20 mTorr) and then isolated from the pyrolysis/vaporizer sub-systems and the vacuum pump by closing isolation valves. Trimethyl aluminum is then dosed into the chamber to total pressure of 500-3000 mTorr, 800-1000 mTorr being optimal, and held in the deposition chamber for 1-20 minutes at temperature of 30° C. to 40° C. The total exposure time is dependent upon the parylene film thickness and the desired depth of infusion of metal precursor. For a 1 micron thick parylene-C film, a 1000 mTorr exposure of trimethyl aluminum for 5-10 minutes is sufficient to infuse trimethyl aluminum 100 nm or more into the parylene film. After completion of the exposure time, the deposition system is pumped to base pressure to evacuate trimethyl aluminum vapor. Optionally, the deposition may be purged or pump/purged with inert gas, such as nitrogen or argon, to aid in trimethyl aluminum removal from the deposition chamber. After removal of trimethyl aluminum, water is dosed into the deposition chamber either by dosing pure water vapor into to deposition chamber or by venting the deposition chamber to atmosphere using filter ambient air, which contains a significant partial pressure of water. The water dosed into the deposition chamber will adsorb onto all exposed surfaces, will diffuse into the parylene film and react with trimethyl aluminum, forming aluminum oxide (AlₓO_{y}) both within and on top of the parylene film. Specifically, water reacts with the aluminum-methyl bond to produce an aluminum-oxygen bond, releasing methane in the process. The stoichiometric reaction is as follows:

2Al(CH₃)₃+3H₂O→Al₂O₃+6CH₄.

Diffusion, or interspersion, of the metal oxide precursor into and on the parylene layer 103 may be controlled by varying the exposure time, process temperature (the rate of diffusion at 100° C. is higher than the rate of diffusion at 20° C.), and partial pressure of precursor vapor in the head space “above” the parylene layer 103

Diffusion, or interspersion, of the metal oxide precursor into and on the parylene layer 103 may be controlled by varying the exposure time, process temperature (the rate of diffusion at 100° C. is higher than the rate of diffusion at 20° C.), and partial pressure of precursor vapor in the head space “above” the parylene layer 103.

The composite coating 100 may include multiple layers of parylene 103, 123 and metal oxide 107, 127, in an alternating arrangement with a parylene layer 103 being the first layer deposited on the substrate 101. The composite coating 100 may have a parylene layer 123 as an outermost layer or it may have a metal oxide layer 127 as an outermost layer. As indicated previously, the number of layers of the composite coating is not limited. The composite coating typically has a total thickness of about and inclusive of 1 μm to about 25 μm. The total thickness of the composite coating may be determined based on the end use of the substrate being coated and any potential size constraints or performance requirements derived based on the end use.

In some embodiments, a coating method may also include the application of a mask to selected regions of the substrate 101 to prevent at least one portion of the coating from being applied to those portions. In embodiments where discrete processes are used to form different portions of a coating, the mask may be present while at least one portion of the coating is applied to the substrate, but absent while at least one other portion of the coating is applied to the substrate; thus, some (masked) portions of the substrate 101 will be covered by fewer portions of a coating than other (unmasked) portions of the substrate. In other embodiments, a mask may remain in place as all portions of a coating are applied to the substrate. As a result, the corrosion resistant coating will not cover those areas of the substrate.

Although the foregoing disclosure provides many specifics, these should not be construed as limiting the scope of any of the ensuing claims. Other embodiments may be devised which do not depart from the scopes of the claims. Features from different embodiments may be employed in combination. The scope of each claim is, therefore, indicated and limited only by its plain language and the full scope of available legal equivalents to its elements.

Reference throughout this specification to features, advantages, or similar language does not imply that all of the features and advantages that may be realized with the subject matter of the present disclosure should be or are in any single embodiment. Rather, language referring to the features and advantages is understood to mean that a specific feature, advantage, or characteristic described in connection with an embodiment is included in at least one embodiment of the present disclosure. Thus, discussion of the features and advantages, and similar language, throughout this specification may, but do not necessarily, refer to the same embodiment.

In the above description, certain terms may be used such as “up,” “down,” “upper,” “lower,” “horizontal,” “vertical,” “left,” “right,” and the like. These terms are used, where applicable, to provide some clarity of description when dealing with relative relationships. But, these terms are not intended to imply absolute relationships, positions, and/or orientations. For example, with respect to an object, an “upper” surface can become a “lower” surface simply by turning the object over. Nevertheless, it is still the same object. Further, the terms “including,” “comprising,” “having,” and variations thereof mean “including but not limited to” unless expressly specified otherwise. An enumerated listing of items does not imply that any or all of the items are mutually exclusive and/or mutually inclusive, unless expressly specified otherwise. The terms “a,” “an,” and “the” also refer to “one or more” unless expressly specified otherwise.

Additionally, instances in this specification where one element is “coupled” to another element can include direct and indirect coupling. Direct coupling can be defined as one element coupled to and in some contact with another element. Indirect coupling can be defined as coupling between two elements not in direct contact with each other, but having one or more additional elements between the coupled elements. Further, as used herein, securing one element to another element can include direct securing and indirect securing. Additionally, as used herein, “adjacent” does not necessarily denote contact. For example, one element can be adjacent another element without being in contact with that element.

As used herein, the phrase “at least one of”, when used with a list of items, means different combinations of one or more of the listed items may be used and only one of the items in the list may be needed. The item may be a particular object, thing, or category. In other words, “at least one of” means any combination of items or number of items may be used from the list, but not all of the items in the list may be required. For example, “at least one of item A, item B, and item C” may mean item A; item A and item B; item B; item A, item B, and item C; or item B and item C. In some cases, “at least one of item A, item B, and item C” may mean, for example, without limitation, two of item A, one of item B, and ten of item C; four of item B and seven of item C; or some other suitable combination.

As used herein, a system, apparatus, structure, article, element, component, or hardware “configured to” perform a specified function is indeed capable of performing the specified function without any alteration, rather than merely having potential to perform the specified function after further modification. In other words, the system, apparatus, structure, article, element, component, or hardware “configured to” perform a specified function is specifically selected, created, implemented, utilized, programmed, and/or designed for the purpose of performing the specified function. As used herein, “configured to” denotes existing characteristics of a system, apparatus, structure, article, element, component, or hardware which enable the system, apparatus, structure, article, element, component, or hardware to perform the specified function without further modification. For purposes of this disclosure, a system, apparatus, structure, article, element, component, or hardware described as being “configured to” perform a particular function may additionally or alternatively be described as being “adapted to” and/or as being “operative to” perform that function.

The present subject matter may be embodied in other specific forms without departing from its spirit or essential characteristics. The described embodiments are to be considered in all respects only as illustrative and not restrictive.

What is claimed:

1. A composite coating on a substrate, comprising:
a first parylene layer deposited on a substrate surface of a substrate;
a first metal oxide layer covering the first parylene layer;
a first metal oxide, parylene hybrid layer formed between the first metal oxide layer and the first parylene layer; and
a second parylene layer covering the first metal oxide layer, with the first metal oxide layer interposed between the first and second parylene layers.

2. The composite coating of claim 1, wherein the first and second parylene layers are at least one of parylene A, parylene C, parylene N, parylene D, parylene VT-4, parylene AF-4, or mixtures or derivations of parylene A, parylene C, parylene N, parylene D, parylene VT-4, parylene AF-4.

3. The composite coating of claim 1, wherein the first parylene layer and the second parylene layer are a same parylene material.

4. The composite coating of claim 1, wherein the first metal oxide layer is formed by oxidation of a metal oxide precursor defined by formula I: [M]-(R¹)ₙ, wherein:
M is a metal;
each R¹ is at least one of hydrogen, C₁-C₁₂ alkyl, C₁-C₁₂ alkoxide, halogen, alkyl halide, C₁-C₁₂ alkylamido, di-C₁-C₁₂ alkylamido, optionally substituted cyclopentadienyl; and
n corresponds to an oxidation state of the metal.

5. The composite coating of claim 4, wherein the metal is at least one of aluminum, gallium, magnesium, hafnium, silicon, tantalum, titanium, yttrium, zinc, and zirconium.

6. The composite coating of claim 4, wherein at least one R1 is C₁-C₁₂ alkyl.

7. The composite coating of claim 4, wherein the first parylene layer and the second parylene layer are different parylene materials.

8. The composite coating of claim 1, further comprising a second metal oxide layer covering a surface of the second parylene layer.

9. The composite coating of claim 8, wherein the second metal oxide layer is formed by oxidation of a second metal oxide precursor defined by formula I: [M]-(R¹)ₙ, wherein:
M is a second metal;
each R¹ is at least one of hydrogen, C₁-C₁₂ alkyl, C₁-C₁₂ alkoxide, halogen, alkyl halide, C₁-C₁₂ alkylamido, di-C₁-C₁₂ alkylamido, optionally substituted cyclopentadienyl; and
n corresponds to an oxidation state of the second metal.

10. The composite coating of claim 8, wherein the first and second metal oxide layers each has a thickness between 5 and 50 nm.

11. The composite coating of claim 8, wherein the first parylene layer has a thickness between 0.1 μm and 2 μm.

12. The composite coating of claim 8, wherein the composite coating further comprises additional parylene layers and additional metal oxide layers in an alternating arrangement up to a maximum composite coating thickness between 0.5 μm and 20 μm.

13. A coated corrosive sensitive article comprising:
a corrosive sensitive article comprising a substrate surface; and
a composite coating comprising:
a first parylene layer deposited on a substrate surface of a substrate;
a first metal oxide layer covering the first parylene layer;
a first metal oxide, parylene hybrid layer formed between the first metal oxide layer and the first parylene layer; and
a second parylene layer covering the first metal oxide layer, with the first metal oxide layer interposed between the first and second parylene layers.

14. The coated corrosive sensitive article of claim 13, wherein the first and second parylene layers are at least one of parylene A, parylene C, parylene N, parylene D, parylene VT-4, parylene AF-4, or mixtures or derivations of parylene A, parylene C, parylene N, parylene D, parylene VT-4, parylene AF-4.

15. The coated corrosive sensitive article of claim 13, wherein the first metal oxide layer is formed by oxidation of a metal oxide precursor defined by formula I: [M]-(R¹)ₙ, wherein:
M is a metal;
each R¹ is at least one of hydrogen, C₁-C₁₂ alkyl, C₁-C₁₂ alkoxide, halogen, alkyl halide, C₁-C₁₂ alkylamido, di-C₁-C₁₂ alkylamido, optionally substituted cyclopentadienyl; and
n corresponds to an oxidation state of the metal.

16. A process for depositing a composite coating on a substrate, comprising:
applying a first parylene layer to a substrate surface of a substrate;
depositing a first metal oxide precursor onto a surface of the first parylene layer to cover the first parylene layer;
oxidizing the first metal oxide precursor to form a first metal oxide layer; and
applying a second parylene layer onto a surface of the first metal oxide layer.

17. The process of claim 16, wherein the first and second parylene layers are at least one of parylene A, parylene C, parylene N, parylene D, parylene VT-4, parylene AF-4, or mixtures or derivations of parylene A, parylene C, parylene N, parylene D, parylene VT-4, parylene AF-4.

18. The process of claim 17, wherein the first metal oxide precursor is defined by formula I: [M]-(R¹)ₙ, wherein:
M is a metal;
each R¹ is at least one of hydrogen, C₁-C₁₂ alkyl, C₁-C₁₂ alkoxide, halogen, alkyl halide, C₁-C₁₂ alkylamido, di-C₁-C₁₂ alkylamido, optionally substituted cyclopentadienyl; and
n corresponds to an oxidation state of the metal.

19. The process of claim 16, further comprising depositing a second metal oxide precursor onto a surface of the second parylene layer.

20. The process of claim 19, wherein the second metal oxide precursor is defined by formula I: [M]-(R¹)ₙ, wherein:
M is a second metal;
each R¹ is at least one of hydrogen, C₁-C₁₂ alkyl, C₁-C₁₂ alkoxide, halogen, alkyl halide, C₁-C₁₂ alkylamido, di-C₁-C₁₂ alkylamido, optionally substituted cyclopentadienyl; and
n corresponds to an oxidation state of the second metal.
